(19) United States
(12) Patent Application Publication
(10) Pub. No.: US 2020/0292578 A1
(43) Pub. Date: Sep. 17, 2020

(54) WAFER LEVEL PROBING OF ELECTRICAL BIOSENSORS

(71) Applicant: FemtoDx, Beverly Hills, CA (US)

(72) Inventor: Pritiraj Mohanty, Los Angeles, CA (US)

(73) Assignee: FemtoDx, Beverly Hills, CA (US)

(21) Appl. No.: 16/654,414

(22) Filed: Oct. 16, 2019

Related U.S. Application Data
(63) Continuation of application No. 16/054,853, filed on Aug. 3, 2018, now abandoned.
(60) Provisional application No. 62/540,687, filed on Aug. 3, 2017.

(51) Int. Cl. G01R 1/067; G01R 31/28; G01N 27/414; B01L 3/00

(52) U.S. Cl. CPC G01R 1/06744; G01R 31/2831; G01R 1/06783; B01L 2200/0689; B01L 3/502715; B01L 2200/027; G01N 27/4145

(57) ABSTRACT

Methods, systems and devices related to wafer level probing of electrical biosensors.

### RELATED APPLICATIONS

This application is a continuation of U.S. application Ser. No. 16/054,853, filed Aug. 3, 2018, which claims priority to U.S. Provisional Application No. 62/540,687, filed Aug. 3, 2017, which are incorporated herein by reference in their entirety.

### FIELD

The invention relates generally to methods for probing a wafer of electrical biosensors.

### BACKGROUND

Electrical biosensors have electronic transport properties that are sensitive to a particular biomolecule of interest (“analyte”) or set of analytes. Such properties include but are not limited to resistance, conductance, and transconductance. The performance of an electrical biosensor is determined by the response of one or more electrical property to analyte-dependent stimuli.

### SUMMARY

Methods, systems and devices which are related to wafer level probing of electrical biosensors are descried herein.

In one aspect, a method is described. The method comprises providing a wafer of electrical biosensors in a fluidic environment and probing the wafer with a probe wafer comprising a series of wafer probe tips that are aligned with the electrical biosensors.

Other aspects and features will become apparent from the following detailed description of the invention when considered in conjunction with the accompanying drawings.

### BRIEF DESCRIPTION OF DRAWINGS

FIG. 1 shows a probe head for wafer level microfluidic probing.

FIG. 2 shows a metal probe tip for a probe wafer.

FIG. 3 shows an assembly of a probe wafer, seal and device wafer.

FIG. 4 shows a cross-section schematic of the composite wafer assembly.

FIG. 5 schematically shows how the composite wafer fits onto a probe station chuck.

FIG. 6 shows a schematic of a probe head making connection to the pads on the probe wafer backside.

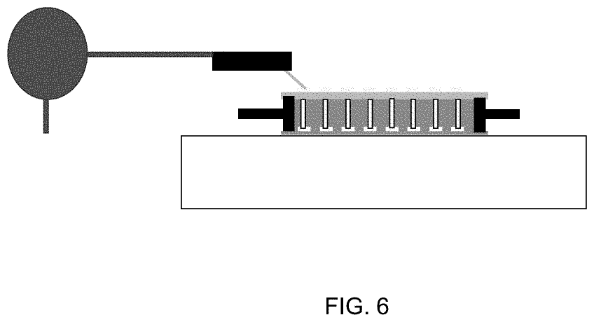

### DETAILED DESCRIPTION

Methods, systems and devices related to wafer level probing of electrical biosensors are described herein. Some embodiments involve probing a wafer of electrical biosensors in fluid to determine the sensors' response to fluid of interest. Such fluids include but are not limited to whole blood, serum, buffer solutions, saline, and custom-made protein-containing solutions. As described further below, some embodiments use a probe wafer that 1) maps directly onto the device wafer; and 2) contains probing pads on one side. A seal may be used to join the probe wafer and device wafer thereby creating a thin fluid-tight chamber. During use, the fluids of interest for measuring sensor performance may be flowed into the chamber in sequence while the back of the probe wafer is electrically probed.

The electrical biosensors are generally produced in dies on a wafer in a scalable microfabrication process. That is, each wafer, which could be one inch in diameter up to 12 inches in diameter or larger, contains tens to thousands of dies. One die can be anywhere from 0.5 mm by 0.5 mm to 2 cm by 2 cm or larger. Each die could be identical, or, more generally, two or more varieties of identical die geometries are present on one wafer. Each die itself contains from one to hundreds of individual sensors. Each sensor, which is nanometer to micrometers in size, is connected to electrical leads that terminate in metal pads. The pads are used as attachment points for external electronics through wire bonding, flip chip, or other methods. These pads are generally larger than 10 microns by 10 microns, up to 1 mm by 1 mm. The pads are arranged in a regular shape around the edges of each die. Analyte samples, including test fluids containing analytes as well as biological fluids, are introduced to the sensor through a microfluidic channel that contains an opening above the sensor region of the die.

Wafer level probing is generally used to perform electrical characterization of dies across a wafer. For this, a probe with a set of probe tips designed to match the die pads is used to make connections to the electrical devices. The probe tips are electrically connected, through wires, a printed circuit, or similar method, to a connector. The connector then interfaces with test measurement equipment such as source meters, lock-in amplifiers, circuitry, and other apparatus dependent on the measurement and characterization method. Either the wafer is lowered and moved, or the probe is lifted and moved, or a combination of both movement methods, to test different dies across the wafer. Such wafer-level device testing methods are used across electronics industries to produce yield maps of devices on a wafer.

For testing the sensitivity of electrical biosensors to analytes, this probing must be modified. The analyte is generally suspended in a biological fluid sample, including but not limited to, blood, sweat, or lacrimal fluid. Therefore, electrical sensors for biomolecules operate in fluid. This means that such sensors can be tested for performance while interacting with the fluid. Sensors are manufactured on a wafer scale, with thousands of individual sensor devices on a single 8″ wafer. To determine yield in the sensing environment, one probes the wafer while each sensor is in the fluidic environment (e.g., under conditions of changing or variable fluid environment).

Prior solutions to the wafer-level probing problem have included attaching a microfluidic chamber to the electrical probe head on a wafer-level probing station. This solution simply integrates the electrical probe with a microfluidic channel. When the probe head is lowered onto the wafer, electrical contact is made to the electrical pads and the microfluidic channel simultaneously seals onto the wafer. Different fluids are then flowed onto the device while the electrical properties are recorded. When the probe is lifted from the wafer both electrical connection and fluidic seal are broken.

Such a method is slow, as the test fluid concentration series is flowed through the chamber for each die, requiring post-test rising for each die tested. Additionally, the proper seal may not be made for each die, resulting in leakage or different flow properties for each tested die on the same wafer. Residual chemicals from one set of fluid flows may remain in the fluid chamber and cross-contaminate the next die. Solutions involving rinsing, heating, or drying are time consuming. Flowing the series for each die successively is also slow, as the time-limiting step becomes the flow rate, which must be slow to prevent turbulence and over pressurizing of the fluid chamber seal.

Another method is to probe the wafer with fluid covering the entire wafer in a thin layer. Here, the probe electrodes continually dip in and out of the fluid as the probe head moves from die to die. This will leave residue on the probe electrodes, which can affect successive measurements. Also, there may be a thin layer of fluid between the probe electrodes and the pads, affecting measurement accuracy and precision. Therefore, a need exists for a true wafer-level probe set-up that is noninvasive with respect to the fluid.

The methods described herein present a solution for wafer level probing in the fluid environment, which provides uniform sample fluid to each die and allows electrical testing to be rapid across the wafer. A standard wafer-level probe station can be used with the methods described herein. The methods described herein may enable rapid wafer-level testing of individual biosensor dies under identical fluidic conditions. The methods also enable rapid transfer of the fluid for rapid testing of the same wafer in different environments.

In some embodiments, the single-die-sized microfluidic chamber is replaced with a wafer-sized thin fluid cavity. Some embodiments involve the use and design of a special probe wafer containing probe pins on one side and probe pads on the other side. The probe pins are laid out to exactly match the probe pads on the device wafer in a one-to-one mapping.

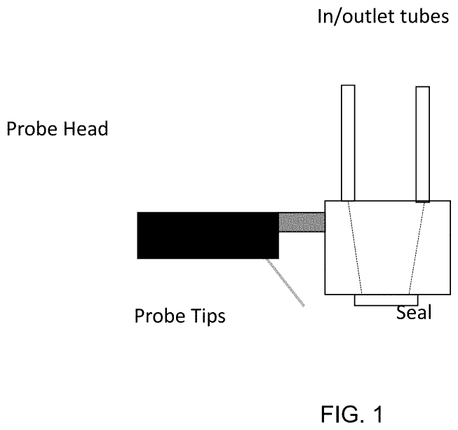

The probe pins are mounted on the probe wafer through vias, and are electrically contiguous with the probe pads on the back side of the probe wafer. The probe pins are sealed into the vias with a fluid-tight sealing method, including but not limited to epoxy, resin, superglue, or cement. A schematic of one such embodiment, of the probe pin using a sealed through via, is shown in FIG. 1. The probe head contains a microfluidic channel that seals to each die for testing, then is lifted and moved to the next die. The seal is made and broken for each die, and all fluids are flowed through the channel for each die. Cross contamination of dies and fluids may occur, in some cases.

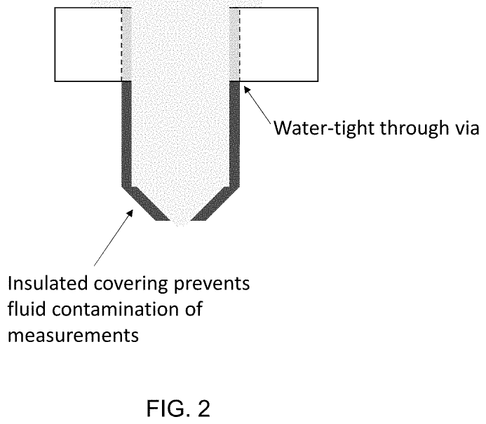

FIG. 2 shows a metal probe tip including a Figure through via. Each probe contains a pad on one side and a tip on the other, while the probe fits into a through via in the probe wafer. The through via is sealed, and the probe may contain an insulating cover everywhere except the very tip.

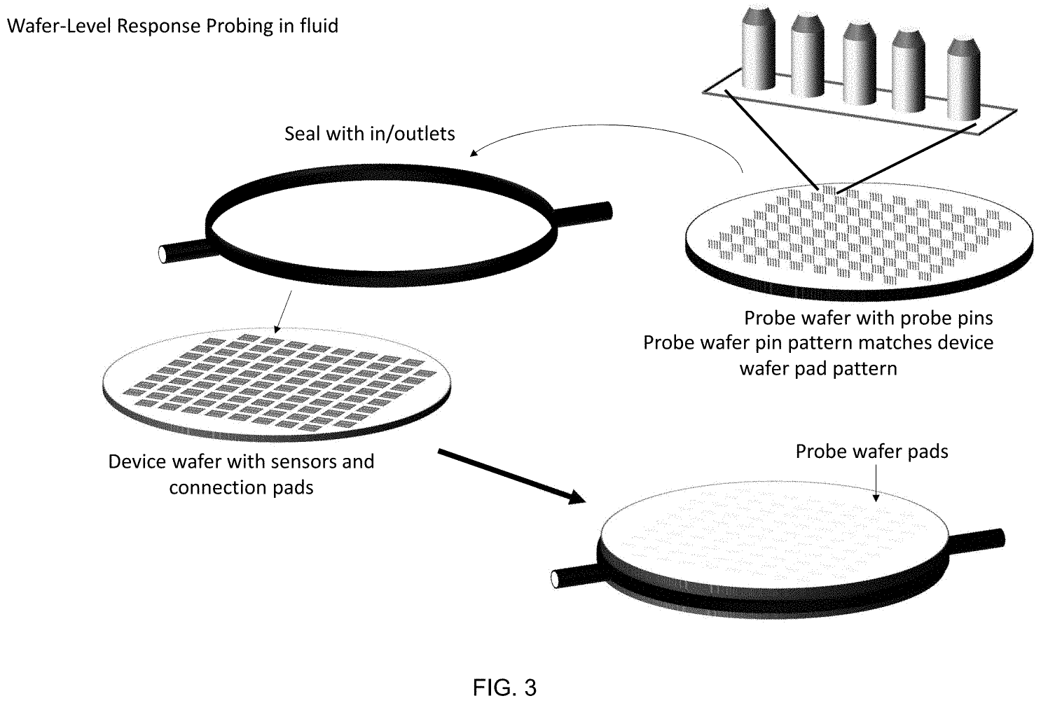

FIG. 3 shows an assembly of the different components: the probe wafer, the seal, and the device wafer. The device wafer may be created in a foundry and contains the sensor components and connection pads. The probe wafer includes a wafer with metal pins on one side and pads on the other, each pin-pad being like that in FIG. 2. The pins are arranged to match the connection pads on the device wafer, so that electrical connection is made to each device in a 1 to 1 mapping on the back of the probe wafer. The seal comprises a polymer, rubber, or otherwise water-tight material, formed into a circle that fits onto the rim of the device wafer. The seal may contain inlet and outlet ports for flowing fluid onto the wafer. The three components are stacked with the seal in the middle and the probe wafer pins connecting to the device wafer. In this manner, a new composite wafer is created with a thin microfluidic channel extending across the entire wafer.

In some embodiments, the probe wafer uses spring-loaded pogo pins. In certain embodiments, the probe wafer pins are rigid and design must be careful to avoid puncturing the device wafer. In other embodiments, the probe pins are bent to allow spring loaded contact, similar to probe tips on a probe station. It should be understood that the methods described herein are not limited to any specific probe tip design.

In some embodiments, the probe pins are coated with an insulating material except at the tip where contact is made to the device wafer. Such an embodiment removes the possibility of measuring electrical characteristics of the fluid instead of the devices.

A water-tight sealing mechanism (“seal”) is placed onto the device wafer and the probe wafer is placed on top and pressed until the seal becomes fluid tight and electrical connection is made between the probe wafer and the device wafer. The seal is a polymer, rubber, or otherwise water-tight, flexible material manufactured into a circle with an outer diameter similar to the wafer diameter.

In some embodiments, the pads on the backside of the probe wafer are arranged in the same pattern as the pads on the device wafer. In some embodiments, the pads are oriented differently for ease of probing.

In some embodiments, the seal contains built-in inlet and outlet pipes for introducing and removing different fluids.

This stack forms a fluid chamber across the entire wafer as shown schematically in FIG. 2. A side cut-out view of the completed mechanism is illustrated in FIG. 3.

In some embodiments, the seal and wafers are designed to so that the device and probe wafers automatically align to each other when sealed. Methods for this include but are not limited to: notching the wafers and adding components to the seal that fit into the notches; etching grooves in the wafers that align with the inlet and outlet channels; designing the seal to align with the wafer flat edges.

In some embodiments, the probe wafer contains a groove into which the seal fits. In some embodiments, the seal is permanently adhered to the probe wafer.

In some embodiments, a set of hinges, clamps, or other locking mechanisms hold the structure together.

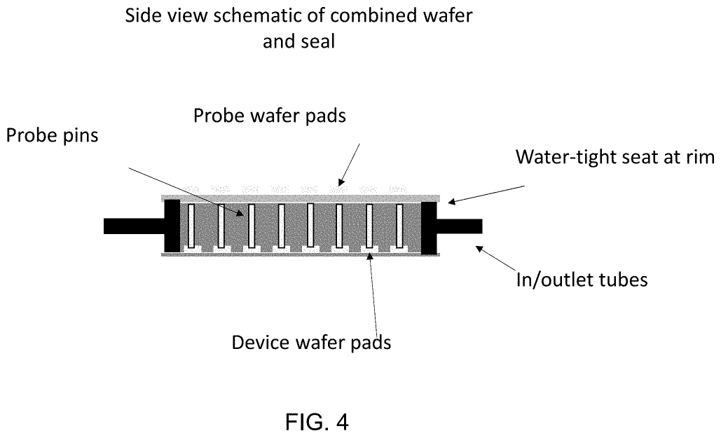

FIG. 4 illustrates a cross-section schematic of the composite wafer, showing probe pads on top, probe pins extending through the interior, a water-tight seal at the rim, inlet and outlet ports, and the device wafer on the bottom.

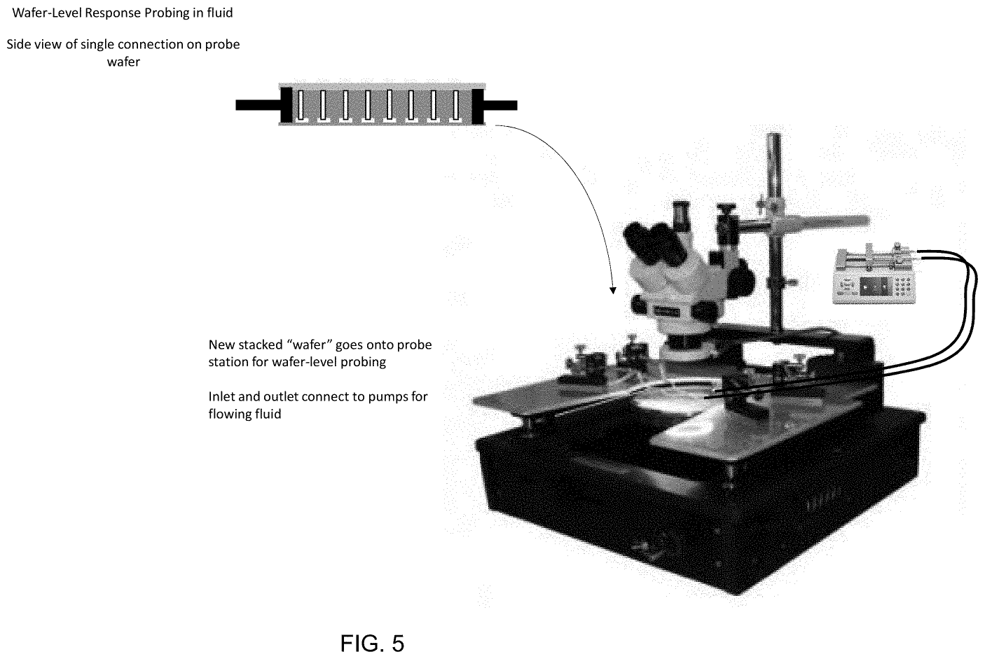

Once the stacked wafer structure is formed, it is ready to be probed to determine device performance. For this, the entire structure is placed on the chuck of a probe station, as shown in FIG. 5. The probe head, attached to an automated probe arm, makes connections to the pads on the back side of the probe wafer. The entire wafer is probed by connecting to the pads of the probe wafer. Fluid can be introduced with a syringe pump or other pumping mechanism. The probe measures each die in given fluid before the fluid is exchanged. The electrical characterization of each device is rapid, and the entire wafer can be probed for each type of fluid in the same time it takes to probe a wafer.

In embodiments where the seal contains built-in inlet and outlet pipes for introducing and removing different fluids, changing the fluid that is to be characterized is achieved by keeping the seal and pumping fluid into or out of the chamber. For example, a concentration series calibration can be performed by flowing first a buffer solution, then a fluid with one particular analyte concentration, then a wash, then another analyte concentration, etc. Each different fluid in this embodiment enters from the inlet pipe and exits through the outlet pipe.

In some embodiments, positive pressure is used, while negative pressure is used in other embodiments. In some embodiments, a single syringe pump is used to flow a pre-arranged series of fluids into the wafer for testing. In certain embodiments, a multi-port pump is used to pump different fluid into the wafer in a certain sequence. In certain embodiments, the syringe pump is integrated into the probe station.

In other embodiments, the probe wafer is lifted to break the fluid seal, and the fluid is exchanged by dumping and pouring.

What is claimed is:

1. A method comprising:
providing a wafer of electrical biosensors in a fluidic environment; and
probing the wafer with a probe wafer comprising a series of wafer probe tips that are aligned with the electrical biosensors.
